(19) United States
(12) Patent Application Publication
(10) Pub. No.: US 2014/0048899 A1
(43) Pub. Date: Feb. 20, 2014

(54) LOW DAMAGE LASER-TEXTURED DEVICES AND ASSOCIATED METHODS

(71) Applicant: SIONYX, INC., (US)

(72) Inventors: Jason Sickler, Arlington, MA (US); Christopher Vineis, Watertown, MA (US); James E. Carey, Waltham, MA (US)

(73) Assignee: SIONYX, INC., Beverly, MA (US)

(21) Appl. No.: 13/764,512

(22) Filed: Feb. 11, 2013

Related U.S. Application Data
(60) Provisional application No. 61/597,573, filed on Feb. 10, 2012.

(51) Int. Cl. H01L 31/18; H01L 31/0236

(52) U.S. Cl. CPC H01L 31/1804; H01L 31/02363
USPC 257/436; 438/71

(57) ABSTRACT

Methods for laser processing semiconductor materials for use in optoelectronic and other devices, including materials, devices, and systems associated therewith are provided. In one aspect, a method of minimizing laser-induced material damage while laser-texturing a semiconductor material can include delivering short pulse duration laser radiation to a target region of a semiconductor material to form a textured region having a reorganized surface layer, wherein the laser radiation has a wavelength from about 200 nm to about 600 nm and a pulse duration of from about 10 femtoseconds to about 400 picoseconds, and wherein defect density of the semiconductor material from beneath the reorganized surface layer up to a depth of about 1 micron is less than or equal to about 10¹²/cm³.

### PRIORITY DATA

This application claims the benefit of U.S. Provisional Patent Application Ser. No. 61/597,573, filed on Feb. 10, 2012, which is incorporated herein by reference.

### BACKGROUND

The interaction of light with semiconductor devices is at the core of some important innovations. Optoelectronic devices, such as photovoltaics, photodiodes, and imagers, are used in various technologies, such as for example, solar cells, digital cameras, optical mice, video cameras, cell phones, and the like. Typically, many semiconductor photodetecting devices are formed from a silicon material. When thick enough, silicon is known to absorb a majority of incident visible light having wavelengths in the range of about 300 nm to 900 nm. These factors, combined with its low cost, abundant supply, non-toxicity and the quantum efficiency in the visible spectrum make silicon a top choice for light detecting. However, because of its indirect bandgap, one major limitation to silicon for optical detectors or optical/electrical energy converters is a typical requirement for a relatively thick device layer (typically >100 microns for common devices) to achieve sufficient optical absorption, especially in the infrared light spectrum.

### SUMMARY

The present disclosure provides methods for laser processing semiconductor materials for use in optoelectronic and other devices, including materials, devices, and systems associated therewith. In one aspect, for example, a method of minimizing laser-induced material damage while laser-texturing a semiconductor material is provided. Such a method can include delivering short pulse duration laser radiation to a target region of a semiconductor material to form a textured region having a reorganized surface layer, wherein the laser radiation has a wavelength between about 200 nm to about 600 nm and a pulse duration of from about 10 femtoseconds to about 400 picoseconds, and wherein defect density of the semiconductor material from beneath the reorganized surface layer up to a depth of about 1 micron is less than or equal to about 10¹²/cm³. In one aspect, the laser radiation wavelength can be such that laser radiation photons have energy that is equal to or greater than a direct band gap of the semiconductor material. In another aspect, the semiconductor material can be silicon and the laser radiation wavelength can be less than or equal to about 365 nm. In yet another aspect, the laser radiation wavelength can be between about 200 nm and about 400 nm. In a further aspect, the laser radiation wavelength can be between about 500 nm and about 550 nm. In another aspect, the pulse duration can be from about 50 femtoseconds to about 100 picoseconds, and in yet another aspect from about 500 femtoseconds to about 20 picoseconds. Furthermore, in some aspects the laser radiation can have a fluence of from about 1 kJ/m² to about 10 kJ/m², and in other aspects the laser radiation can be delivered to the target region with a shot number of from about 2 to about 1000.

Additionally, the level of defect density in the semiconductor material can vary. In one aspect, for example, the defect density of the semiconductor material from beneath the reorganized surface layer up to a depth of about 1 micron can be from about 10⁵/cm to about 10⁸/cm³. In another aspect, the defect density of the semiconductor material from beneath the reorganized surface layer up to a depth of about 1 micron can be from about 10⁵/cm to about 10⁶/cm³.

In another aspect, a method of minimizing laser-induced material damage while laser-texturing a semiconductor material can include delivering short pulse duration laser radiation to a target region of a semiconductor material to form a textured region having a reorganized surface layer and surface features with an average height of from about 100 nm to about 2 microns, with an average width of from about 100 nm to about 2 micron, and with an average nearest-neighbor distance of from about 100 nm to about 3 microns, wherein defect density of the semiconductor material from beneath the reorganized surface layer up to a depth of about 1 micron is less than or equal to about 10¹²/cm³. In one specific aspect, the surface features have an average height of from about 500 nm to about 1 micron. In yet another specific aspect, the surface features have an average width of from about 400 nm to about 600 nm. In one aspect, the laser radiation has a wavelength between about 200 nm to about 600 nm and a pulse duration of from about 10 femtoseconds to about 400 picoseconds. In yet another aspect, the laser radiation has a wavelength between about 200 nm and about 400 nm. In other aspects, the laser radiation has a wavelength between about 500 nm and about 550 nm. Regarding pulse duration, in one aspect the laser radiation has a pulse duration of from about 50 femtoseconds to about 100 picoseconds. In another aspect, the laser radiation has a pulse duration of from about 500 femtoseconds to about 20 picoseconds.

The present disclosure additionally provides a laser textured semiconductor device having minimal laser-induced material damage. Such a device can include a semiconductor material, a laser-generated textured region formed on a portion of the semiconductor material, the textured region having a reorganized surface layer, surface features within the textured region, the surface features having an average height of from about 100 nm to about 2 microns, having an average width of from about 100 nm to about 2 micron, and having an average nearest-neighbor distance of from about 100 nm to about 3 microns, and a defect density within the semiconductor material from beneath the reorganized surface layer up to a depth of about 1 micron is less than or equal to about 10¹²/cm³. In one specific aspect, the semiconductor material is silicon. Non-limiting examples of surface features can include cones, pillars, pyramids, microlenses, sphere-like structures, quantum dots, inverted features, and combinations thereof.

### BRIEF DESCRIPTION OF THE DRAWINGS

For a fuller understanding of the nature and advantage of the present disclosure, reference is being made to the following detailed description of various embodiments and in connection with the accompanying drawings, in which:

FIG. 1 shows a cross section diagram of a laser processed semiconductor material in accordance with one aspect of the present disclosure;

FIG. 2 shows an image of a cross section of a laser processed semiconductor material from a traditional laser processing technique;

FIG. 3 shows an image of a cross section of a laser processed semiconductor material in accordance with one aspect of the present disclosure;

FIG. 4 shows a flow diagram of a method of minimizing laser-induced material damage while laser-texturing a semiconductor material in accordance with one aspect of the present disclosure;

FIG. 5 shows a flow diagram of a method of minimizing laser-induced material damage while laser-texturing a semiconductor material in accordance with one aspect of the present disclosure;

FIG. 6 shows an image of a cross section of a laser processed semiconductor material from a traditional laser processing technique; and

FIG. 7 shows an image of a cross section of a laser processed semiconductor material from a traditional laser processing technique.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Definitions

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the terms “light” and “electromagnetic radiation” can be used interchangeably and can refer to light or electromagnetic radiation in the ultraviolet, visible, near infrared, and infrared spectra. The terms can further more broadly include electromagnetic radiation such as radio waves, microwaves, x-rays, and gamma rays. Thus, the term “light” is not limited to electromagnetic radiation in the visible spectrum.

As used herein, the term “laser damage” is used to describe defects introduced into a material as a result of laser processing. Non-limiting examples of such defects can include grain boundaries, dangling bonds, stacking faults, amorphous (non-crystalline) regions, point defects such as vacancies or interstitials, and other crystalline defects known to those skilled in the art.

As used herein, the term “laser processing” refers to the modification of a region of a region of a semiconductor material using a short-pulsed laser to form a textured region or surface.

As used herein, the terms “surface modifying” and “surface modification” refer to the altering of a surface of a semiconductor material using a laser processing technique. In one specific aspect, surface modification can include processes using primarily laser radiation. In another aspect, surface modification can include processes using laser radiation in combination with a dopant, whereby the laser radiation facilitates the incorporation of the dopant into a surface of the semiconductor material. Also, a modified surface can include, for example, a textured surface.

As used herein, the term “textured surface” can refer to a surface having a topology with nanometer to micrometer-sized surface variations formed by irradiation with laser pulses.

As used herein, the term “fluence” refers to the amount of energy from a single pulse of laser radiation that passes through a unit area. In other words, “fluence” can be described as the energy density of one laser pulse.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of”particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

The present disclosure relates to optoelectronic devices, materials, and associated methods. Such devices exhibit increased electromagnetic radiation absorption properties and/or enhanced anti-reflecting properties, while at the same time having reduced semiconductor material imperfections or defects that can result from the manufacturing process. It has been discovered that the inclusion of a specialized region of a semiconductor material can facilitate a more efficient interaction between the semiconductor device and electromagnetic radiation. For example, a laser processed region, such as a region of the semiconductor material that has been textured or surface modified by a pulsed laser, can increase the efficiency of light interaction for many optoelectronic devices. Such a region can exhibit a variety of beneficial properties depending on the design of the device, such as for example, enhanced absorption properties, enhanced anti-reflective properties, and the like. The net result can be an increase in the electrical signal as compared to a non-textured device, thus leading to increased device performance.

A textured region can be formed at any location in or on the semiconductor material, and particularly at locations that provide enhanced functionality of the optoelectronic device. For example, in one aspect the textured region can be formed at a light interacting region. A light interacting region can be defined as a region of the semiconductor material that interacts with light during the functioning of the device. In one aspect, for example, a light interacting region can be the frontside surface of the semiconductor material that receives incident electromagnetic radiation. In another aspect, a light interacting region can be the backside of the semiconductor material that interacts with electromagnetic radiation that has passed through the semiconductor material. In yet another aspect, a light interacting region can be a side region of the semiconductor material that receives redirected electromagnetic radiation. The textured region can be formed at one or more light interacting regions, and the textured region can be formed across the entire region or only a portion thereof, depending on the design of the device. The textured region can function to scatter electromagnetic radiation, to redirect electromagnetic radiation, and/or to absorb electromagnetic radiation, thus increasing the absorptance and/or quantum efficiency of the device. In one aspect, electromagnetic radiation contacts a particular textured region prior to entering the semiconductor material. In another aspect, electromagnetic radiation passes through the semiconductor material prior to contacting a particular textured region. The textured region can include surface features to increase the effective absorption length of the semiconductor device.

As such, in some aspects textured regions can allow an optoelectronic device to experience multiple passes of electromagnetic radiation within the device, particularly at longer wavelengths (i.e. infrared). Such internal redirection of light can thus increase the effective absorption length to be greater than the physical thickness of the semiconductor material. This increase in absorption length in turn increases the quantum efficiency of the device. Additionally, in one aspect, the textured region on the front side of the semiconductor material is anti-reflective, and can thus reduce reflection of the light impinging thereon. Such reduced reflection can further increase the proportion of light entering into the semiconductor material. Thus, an anti-reflective surface can increase the efficiency of the device by decreasing light loss that can result due to reflection.

A variety of techniques of laser processing to form a textured region are contemplated, and any technique capable of forming such a region is considered to be within the present scope. Laser treatment or processing can allow for, among other things, enhanced absorption properties and thus increased electromagnetic radiation detection. In one aspect, for example, a target region of the semiconductor material can be irradiated with pulsed laser radiation to form a textured region. Examples of such processing have been described in further detail in U.S. Pat. Nos. 7,057,256, 7,354,792 and 7,442,629, which are incorporated herein by reference in their entireties. Briefly, a surface of a semiconductor material is irradiated with laser radiation to form a textured or surface modified region. Such laser processing can occur with or without a dopant material. In those aspects whereby a dopant is used, the laser can be directed through a dopant carrier and onto the semiconductor material. In this way, dopant from the dopant carrier is introduced into the target region of the semiconductor material. Such a region incorporated into a semiconductor material can have various benefits in accordance with aspects of the present disclosure. For example, the textured region typically has surface features and/or a textured layer that increases the probability of electromagnetic radiation absorption. In one aspect, such a textured region is a substantially textured surface including micron-sized and/or nano-sized surface features that have been generated by the laser texturing. In another aspect, irradiating the semiconductor material includes exposing the laser radiation to a dopant such that irradiation incorporates the dopant into the semiconductor. Various dopant materials are known in the art, and are discussed in more detail herein.

As has been described, however, sometimes a laser texturing processes can introduce damage and/or other lattice changes into the semiconductor material as the laser is ablating, melting, and allowing the semiconductor to solidify. In some cases, laser damage can have detrimental effects on the semiconductor material functionality, such as, for example, reduced minority-carrier lifetime and/or reduced majority-carrier mobility. In turn these effects can result in reduced photocarrier collection and/or reduced signal. For many optoelectronic devices, such laser damage to the crystalline structure of the semiconductor can result in increased dark current and/or reduced quantum efficiency and device performance. Accordingly, by reducing a portion, substantially all, or all of the laser damage introduced as a result of laser texturing a semiconductor surface, the photocarrier collection and signal magnitude of the affected material can be increased, in some cases consistent with near bulk semiconductor or doped semiconductor levels.

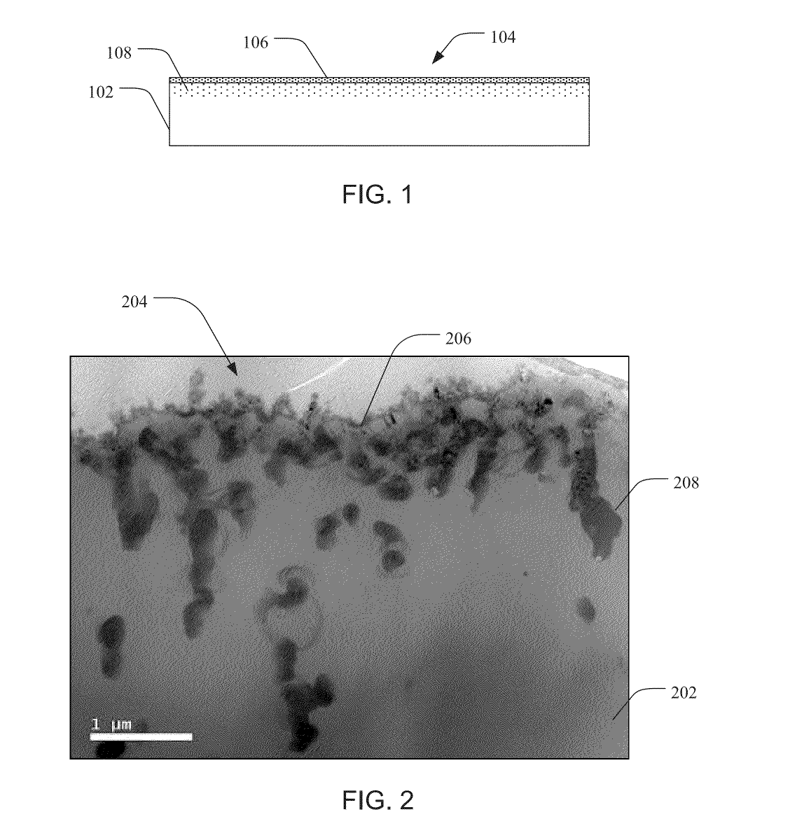

Laser texturing techniques based on melting and/or ablation can been used to remove less material and reduce lateral damage compared to other texturing techniques such as mechanical abrasion, chemical etching, and the like. As such, laser radiation is applied to a semiconductor surface to form a textured region having surface features as is explained more fully below. In addition to such surface features, additional alterations to the semiconductor material can occur, depending on the physical nature of the semiconductor and the characteristics of the laser radiation. Such alterations can be beneficial, detrimental, or have no effect on the functionality of the resulting device. Furthermore, effects on functionality can be dependent on the type or location of the laser alteration. For example, FIG. 1 shows a depiction of a semiconductor material 102 that has been laser processed on a now textured surface 104. The textured surface 104 can include surface features of various shapes, sizes, and distributions (not shown). In many cases, laser processing can produce a thin layer where the semiconductor lattice has been altered or otherwise reorganized. This reorganized layer 106 can exhibit an altered semiconductor lattice, laser damage, dopant concentration, carrier concentration, mobility, minority carrier lifetime, optical absorption, crystallinity, and tends to be very thin, on the order of about 10 nm to about 100 nm or so. Beneath the reorganized layer 106 is a region of the semiconductor material that can exhibit varying amounts of laser-related damage, depending on a variety of factors. This damage-variable region 108 can greatly affect the absorptance properties of the semiconductor device depending on the level of damage contained therein. The delineation between the reorganized layer 106 and the damage-variable region 108 can be relatively distinct, allowing visualization of the boundary with appropriate imaging metrology.

One example of a laser processed semiconductor is shown in FIG. 2. The image shows a semiconductor material 202 that has been sectioned to show a slice that was approximately parallel to the direction of the incoming laser radiation. A reorganized layer 206 extends across the surface that has been textured (i.e. the textured surface 204). Darker areas of laser damage 208 extend downward into the semiconductor material 202 in the direction of the laser radiation. In this case, these areas of laser damage 208 are clusters of defects caused by the laser that can reduce the overall functionality of the semiconductor material/device.

The inventors have discovered techniques of reducing laser damage introduced into this underlying damage-variable region during laser texturing of the semiconductor material. Not only do such techniques increase the functionality of the resulting semiconductor material, but they also allow a reduction or elimination of the need for post-texturing chemical etching or other methods of damage reduction and/or removal.

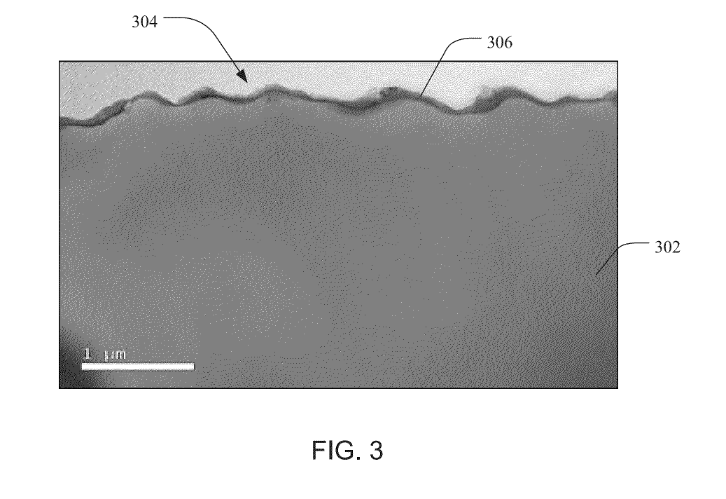

FIG. 3 shows an example image of a semiconductor material that has been laser textured according to aspects of the present disclosure. The image shows a semiconductor material 302 that has been sectioned to show a slice that was approximately parallel to the direction of the incoming laser radiation. A reorganized layer 306 extends across the surface that has been textured (i.e. the textured surface 304). Note the absence of the striking darker areas of laser damage that were shown in FIG. 2 in the direction of the laser radiation. Such can be accomplished through the manipulation of various laser radiation characteristics to minimize or eliminate the introduction of laser-related damage below the reorganized layer 306.

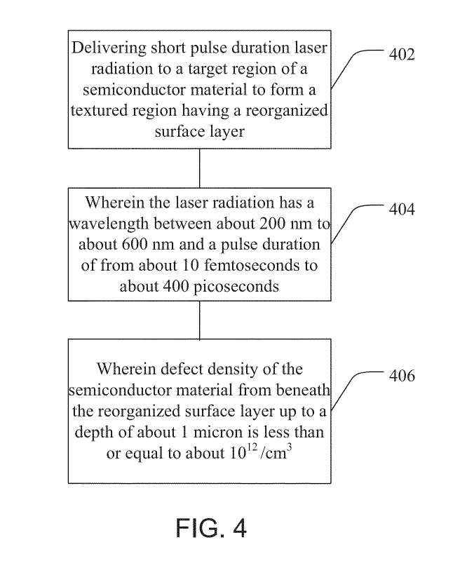

In one aspect, for example, as is shown in FIG. 4, a method of minimizing laser-induced material damage while laser-texturing a semiconductor material can include 402 delivering short pulse duration laser radiation to a target region of a semiconductor material to form a textured region having a reorganized surface layer, 404 wherein the laser radiation has a wavelength between about 200 nm to about 600 nm and a pulse duration of from about 10 femtoseconds to about 400 picoseconds, and 406 wherein defect density of the semiconductor material from beneath the reorganized surface layer up to a depth of about 1 micron is less than or equal to about 10¹²/cm³. Thus, by irradiating the semiconductor material with laser radiation having wavelengths in the ultraviolet (UV) to green range and a short pulse duration, defects in the semiconductor material beneath the reorganized layer can be greatly reduced or even eliminated. The degree of damage reduction achieved according to aspects of the present disclosure can vary depending on the parameters of the laser processing procedure, the characteristics of the laser radiation being used, and the desired texture/surface features. Generally, the degree of damage reduction obtained through the utilization of laser radiation having a center wavelength of less than about 600 nm combined with a pulse duration of less than about 400 picoseconds is considered to be within the present scope.

In some aspects, any damage introduced into the semiconductor material by the laser radiation is undetectable from the background defect density of the semiconductor. In other words, the laser radiation has not generated any defects or any substantial defects in the region beneath the reorganized layer. In another aspect, defect density of the semiconductor material from beneath the reorganized surface layer up to a depth of about 1 micron is less than or equal to about 10¹⁰/cm³, or less than 10⁸/cm³, or less than 10⁶/cm³. In another aspect, the defect density of the semiconductor material from beneath the reorganized surface layer up to a depth of about 1 micron is from about 10⁵/cm³ to about 10⁸/cm³. In a further aspect, the semiconductor material is single crystal silicon, and the defect density of the silicon material from beneath the reorganized surface layer up to a depth of about 1 micron is from about 10⁵/cm³ to about 10⁸/cm³. In a further aspect, the defect density of the semiconductor material from beneath the reorganized surface layer up to a depth of about 1 micron is from about 10⁵/cm³ to about 10⁶/cm³. In yet a further aspect, the semiconductor material is single crystal silicon, and the defect density of the silicon material from beneath the reorganized surface layer up to a depth of about 1 micron is from about 10⁵/cm³ to about 10⁶/cm³. It is noted that the defect density in a typical single crystal silicon wafer is from about 10⁵/cm³ to about 10⁶/cm³, thus indicating that methods according to aspects of the present disclosure can introduce nominal defects, substantially no defects, or no defects due to the laser within this semiconductor region. In other aspects, defect density can be described in terms of the multiplicative increase in defects in the laser processed material as compared to the baseline number of defects in the starting material. For example, in one aspect the defect density of the semiconductor material from beneath the reorganized surface layer up to a depth of about 1 micron can be from about 10° to about 10⁷ times greater than the defect density of the semiconductor material prior to laser processing. In another aspect, the defect density of the semiconductor material from beneath the reorganized surface layer up to a depth of about 1 micron can be from about 10° to about 10⁵ times greater than the defect density of the semiconductor material prior to laser processing. In yet another aspect, the defect density of the semiconductor material from beneath the reorganized surface layer up to a depth of about 1 micron can be from about 10° to about 10³ times greater than the defect density of the semiconductor material prior to laser processing.

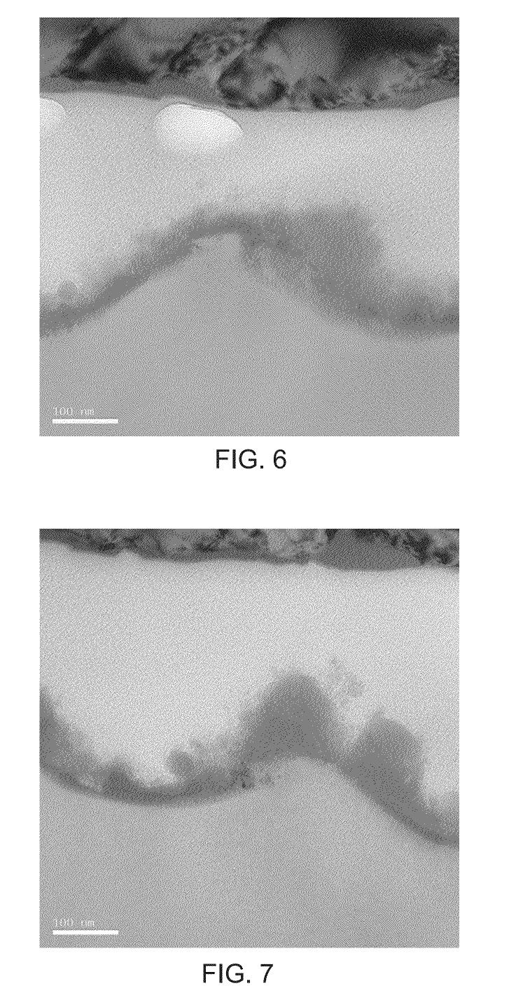

For comparison, the laser texturing in FIG. 2 was performed on a single crystal silicon wafer that normally has a background defect density of from about 10⁵/cm³ to about 10⁶/cm³. The texture was generated using a laser having a wavelength of about 1064 nm and pulse durations of about 10 ps. The region below the reorganized layer 206 in this figure has an average defect density of at least 10¹⁴/cm³, indicating a very high degree of damage generated by laser radiation at this wavelength and pulse duration. In contrast, the laser texturing in FIG. 3 was performed on a similar silicon wafer having a similar degree of background defect density. The texture was generated using a laser having a wavelength of about 355 nm and pulse durations of about 10 ps. The region below the reorganized layer 306 in this figure is essentially free or substantially free of additional defects or at least defect clusters beyond the background level of the silicon wafer (about 10⁵/cm³ to about 10⁶/cm³). Thus, delivering laser radiation having a wavelength between about 200 nm and about 600 nm with a pulse duration of from about 10 femtoseconds to about 400 picoseconds can greatly reduce the amount of damage generated in the semiconductor material beneath the reorganized layer. Two additional examples of samples formed using similar conditions are shown in FIGS. 6 and 7.

While the laser texturing process typically involves significant nonlinear behavior, the linear absorption of the semiconductor material can be important. To minimize thermal damage in the semiconductor beneath the reorganized layer it can be desirable for the radiation to be absorbed over a short distance at the semiconductor material interface, and in a short time compared to thermal timescales. As such, it can be beneficial for the laser radiation photon energies used to be above the semiconductor material bandgap energy, with the laser radiation delivered in short pulses. For indirect bandgap materials such as silicon, it can be further advantageous to use laser radiation with photon energies above or about the direct bandgap energy, which is generally greater than the indirect bandgap energy. Thus in one aspect it can be particularly beneficial to select laser radiation having photon energies with the highest linear absorption. For silicon, this means using radiation with a center wavelength of about 365 nm or less.

As such, shorter linear absorption lengths can reduce the need for additional nonlinear absorption. This in turn makes the process more tolerant of pulse duration variations, peak power fluctuations, and generally can make the laser texturing process more robust. Additionally, high linear absorption allows the achievement of higher energy densities in the material use lower levels of laser power, thereby enabling a process with less power and/or higher process throughput.

Thus the type of laser radiation used to surface modify a semiconductor material can vary depending on the semiconductor material, the intended modification, the acceptable level of laser-induced damage, and the like. Any laser radiation known in the art can be used with the devices and methods of the present disclosure. There are a number of laser characteristics, however, that can affect the surface modification process and/or the resulting product including, but not limited to the wavelength of the laser radiation, beam size, beam shape, pulse duration, fluence, pulse frequency, polarization, laser propagation direction relative to the semiconductor material, degree of coherence, etc. In one aspect, a laser can be configured to provide pulsatile lasing of a semiconductor material. A short-pulsed laser is one capable of producing femtosecond, picosecond and/or nanosecond pulse durations.

Laser pulses according to aspects of the present disclosure that allow texturing while minimizing semiconductor damage can have a central wavelength in a range of about from about 100 nm to about 600 nm. It is noted that the present scope includes any laser radiation wavelength below about 600 nm that is capable of texturing a semiconductor surface with short pulse durations. In one aspect, for example, the laser radiation wavelength can be between about 200 nm and about 400 nm. In another aspect, the laser radiation wavelength is between about 500 nm and about 550 nm. The pulse duration of the laser radiation can be in a range of from about tens of femtoseconds to about hundreds of nanoseconds. In one aspect, laser pulse durations can be in the range of from about 10 femtoseconds to about 500 picoseconds. In another aspect, laser pulse durations can be in the range of from about 50 femtoseconds to about 100 picoseconds. In another aspect, laser pulse durations can be in the range of from about 500 femtoseconds to about 20 picoseconds.

The fluence of each laser pulse can also vary depending on the desired results of the texturing procedure and the characteristics of the laser radiation being used. In one aspect, for example, the fluence can be from about 1 kJ/m² to about 20 kJ/m², or in another aspect from about 1 kJ/m² to about 10 kJ/m². It is noted that the size of the features in the textured region can be related to the fluence of the laser radiation. On average, a lower laser fluence results in smaller features, while a higher laser fluence results in larger features. Other factors that can affect surface morphology include laser polarization and laser propagation direction relative to the irradiated semiconductor surface. Typically, the fluence required to achieve the desired textured surface characteristics will decrease as the wavelength is reduced.

The number of laser pulses irradiating a target region is often called the shot number, and can vary widely depending on the intended texturing process. In one aspect, the shot number can be in a range of from about 1 to about 2000. In another aspect, the shot number can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. In another aspect, the repetition rate or frequency of the pulses can be selected to be in a range of from about 1 kHz to about 450 kHz.

Further, the environment in which the semiconductor material is laser processed can affect characteristics of the textured region, such as, for example, the size of the surface features. For example, lasing the semiconductor material in a liquid can create smaller features than lasing in gas. Other examples include lasing in a vacuum, in a chamber with a controlled gas, in open air, in open air with one or more gasses flowing over the surface, and the like. This environment can include any molecule and/or compound that allows laser texturing functionality. Non-limiting examples can include molecules and/or compounds that contain phosphorus, boron, arsenic, fluorine, chlorine, sulfur, nitrogen, oxygen, germanium, carbon, helium, neon, argon, krypton, xenon, radon, and the like, including appropriate mixtures thereof. Other examples can include, without limitation, sulfur hexafluoride, diatomic nitrogen, air, noble gases (He, Ne, Ar, Kr, Xe, Rn), and the like. Other liquids, solids, gasses, and plasmas are also contemplated. The process of lasing the semiconductor material in a liquid is described in U.S. patent application Ser. No. 12/038,209, filed on Feb. 27, 2008, which is incorporated herein by reference in its entirety.

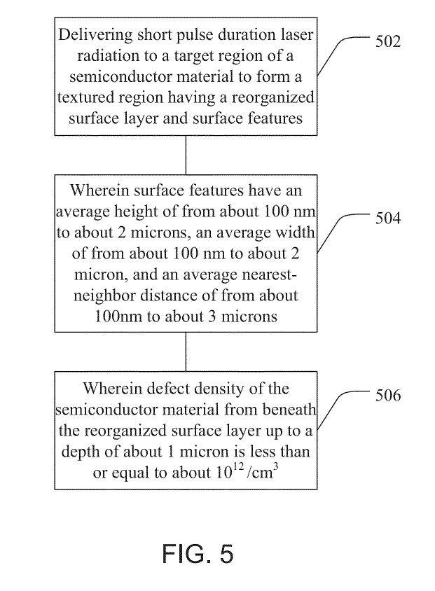

As is shown in FIG. 5, a method of minimizing laser-induced material damage while laser-texturing a semiconductor material is provided including 502 delivering short pulse duration laser radiation to a target region of a semiconductor material to form a textured region having a reorganized surface layer and surface features with 504 an average height of from about 100 nm to about 2 microns, with an average width of from about 100 nm to about 2 microns, and with an average nearest-neighbor distance of from about 100 nm to about 3 microns, wherein 506 defect density of the semiconductor material from beneath the reorganized surface layer up to a depth of about 1 micron is less than or equal to about 10¹²/cm³.

Additionally, in some aspects the present disclosure provides a laser textured semiconductor device having minimal laser-induced material damage. Such a device can include a semiconductor material, a laser-generated textured region formed on a portion of the semiconductor material, the textured region having a reorganized surface layer, surface features within the textured region, the surface features having an average height of from about 100 nm to about 2 microns, having an average width of from about 100 nm to about 2 microns, and having an average nearest-neighbor distance of from about 100 nm to about 3 microns, and a defect density within the semiconductor material from beneath the reorganized surface layer up to a depth of about 1 micron is less than or equal to about 10¹²/cm³. In addition, in some aspects the surface features can have an average height of from about 500 nm to about 1 micron. In other aspects, surface features can have an average width of from about 400 nm to about 600 nm.

As has been described, the textured region of the semiconductor material can include surface features that have been generated by the laser treatment such as microstructures, nanostructures, and/or patterned areas on the surface and, if a dopant is used, the incorporation of such dopants into the semiconductor material. The surface features can have a variety of configurations depending on the laser processing conditions used to form the textured region. The surface features can be, without limitation, cones, pyramids, pillars, protrusions, microlenses, sphere-like structures, quantum dots, and the like, including inverted surface features and appropriate combinations thereof.

Additionally, the surface features can be micron-sized, nano-sized, or a combination thereof. For example, cones, pyramids, protrusions, and the like can have an average height within this range. In one aspect, the height of a particular feature would be measured from the base of the feature to the distal tip of the feature. In another aspect, the height of a particular feature would be measured from the surface plane upon which the feature was created to the distal tips of the feature. As another example, quantum dots, microlenses, and the like can have an average diameter within the micron-sized and/or nano-sized range.

In another aspect of the present disclosure, at least two laser beams can be directed to interfere with one another in order to influence the dimensions of the resulting texture's dominant lateral features. In this manner, features substantially larger than the wavelength of the light used can be encouraged. This can be desirable for controlling the functioning of the textured surface. For example, texture lateral spacing can be made larger to reduce the “effective index” functioning of the texture, and increase the scattering behavior. While this describes the interference of distinct beams, this also contemplates and includes all manner of pattern formation through diffraction and interference. This includes, but is not limited to, the use of diffractive masks, apertures, phase plates, and other beam shaping elements.

This approach is distinct from photolithography in various ways. Photolithography typically uses light to expose a photoresist, which is subsequently processed and used to control later processing steps. Here, there is no explicit mask, no photoresist, and no explicit mechanism for the laser interference pattern to control a subsequent step's action. Also, photolithographic processes requirement multiple steps, whereas this process is a self-contained “single step”.

In one aspect, two to four beams with center wavelengths in the range of about 340 nm and about 360 nm are interacted together to encourage lateral feature spacing greater than 340 nm. In another aspect, two to four beams with center wavelengths at about one or more of the wavelengths selected from 248 nm, 343 nm, and 355 nm are interacted to encourage lateral feature spacing between 500 nm and 3000 nm.

Many short pulse lasers with sufficient power to quickly process material achieve their increased power by operating at higher repetition frequencies. As a result, higher power lasers tend to have less time between subsequent pulse impacts. For laser texturing, this increases the risk that thermal energy can build up over many pulse impacts, which can lead to increased damage to the underlying material. Additionally, if the light-matter interaction zone has an environment that is altered by the laser processing, the environment may not have a chance to completely equilibrate before the next pulse arrives, thereby changing the nature of subsequent light-matter interactions. For example, in a gas environment where a pulse changes the gas in the vicinity of the light-matter interaction zone, subsequent pulses will encounter a different environment if unchanged gas cannot diffuse to the vicinity of the interaction zone between pulses. In order to control the laser texturing dynamics, while still taking advantage of these high repetition rates, high power lasers, the spatial and temporal occurrence of pulse impacts can be redistributed. Stated differently, for a given set of planned pulse impact locations, the time at and order in which each occurs can be altered. Specifically, to reduce the risk of thermal buildup and/or environment alteration, and still enable low-damage and damage-free “single step” laser texturing, the temporal redistribution of impact locations can be chosen so that any given location is not impacted too frequently over a given time. As such, thermal energy has more time during which to dissipate, and the environment has more time to equilibrate, replenish, or otherwise substantially return to its former state before another pulse impact occurs. This helps to ensure that each pulse impact event occurs in substantially the same environment (except, of course, for the changes intended by performing the laser exposure in the first place), and is independent from other pulse impact events. This can also improve surface texture uniformity across the target zone from center to edge. In cases that “scan-and-step” rastering is used to process a given material surface area, this approach will also reduce or eliminate any artifacts that result from the rastering that would otherwise distinguish the scanning direction from the stepping direction.

Likewise, pulse impact events can be made to not be independent by ensuring that neighboring impact locations occur closer in time. For example, this could be used to reduce laser power requirements. In this example, the residual thermal energy is used to effectively lower the laser texturing threshold (be it driven by ablation, melting or other phenomenon). As another example, a method could include dissociating a gas environment so that the subsequent pulse exposed functions as though it were in a vacuum. Other goals are contemplated and can be pursued by the redistribution of when and where a planned set of pulse impact locations occur, and are considered in scope.

It is noted that various damage removal and subsequent processing of the semiconductor material following texturing is also contemplated, and that the levels of defect densities described herein are levels that are achieved prior to any subsequent damage removal processing. Various damage removal techniques are described in U.S. patent application Ser. No. 13/333,482, filed on Dec. 21, 2011, which is incorporated by reference. Additionally, it is also contemplated that the semiconductor material can be optionally thermally annealed following laser processing in order to further reduce defect density.

Of course, it is to be understood that the above-described arrangements are only illustrative of the application of the principles of the present disclosure. Numerous modifications and alternative arrangements may be devised by those skilled in the art without departing from the spirit and scope of the present disclosure is intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of minimizing laser-induced material damage while laser-texturing a semiconductor material, comprising:
delivering short pulse duration laser radiation to a target region of a semiconductor material to form a textured region having a reorganized surface layer, wherein the laser radiation has a wavelength of from about 200 nm to about 600 nm and a pulse duration of from about 10 femtoseconds to about 400 picoseconds, and wherein defect density of the semiconductor material from beneath the reorganized surface layer up to a depth of about 1 micron is less than or equal to about 10¹²/cm³.

2. The method of claim 1, wherein the laser radiation wavelength is such that laser radiation photons have energy that is equal to or greater than a direct band gap of the semiconductor material.

3. The method of claim 2, wherein the semiconductor material is silicon and the laser radiation wavelength is less than or equal to about 365 nm.

4. The method of claim 1, wherein the laser radiation wavelength is from about 200 nm to about 400 nm.

5. The method of claim 1, wherein the laser radiation wavelength is from about 500 nm to about 550 nm.

6. The method of claim 1, wherein the pulse duration is from about 50 femtoseconds to about 100 picoseconds.

7. The method of claim 1, wherein the pulse duration is from about 500 femtoseconds to about 20 picoseconds.

8. The method of claim 1, wherein the laser radiation has a fluence of from about 1 kj/m² to about 10 kj/m².

9. The method of claim 1, wherein the laser radiation is delivered to the target region with a shot number of from about 2 to about 1000.

10. The method of claim 1, wherein the defect density of the semiconductor material from beneath the reorganized surface layer up to a depth of about 1 micron is from about 10⁵/cm to about 10⁸/cm³.

11. The method of claim 1, wherein the defect density of the semiconductor material from beneath the reorganized surface layer up to a depth of about 1 micron is from about 10⁵/cm to about 10⁶/cm³.

12. A method of minimizing laser-induced material damage while laser-texturing a semiconductor material, comprising:
delivering short pulse duration laser radiation to a target region of a semiconductor material to form a textured region having a reorganized surface layer and surface features with an average height of from about 100 nm to about 2 microns, with an average width of from about 100 nm to about 2 micron, and with an average nearest-neighbor distance of from about 100 nm to about 3 microns, wherein defect density of the semiconductor material from beneath the reorganized surface layer up to a depth of about 1 micron is less than or equal to about 10¹²/cm³.

13. The method of claim 12, wherein the surface features have an average height of from about 500 nm to about 1 microns.

14. The method of claim 12, wherein the surface features have an average width of from about 400 nm to about 600 nm.

15. The method of claim 12, wherein the defect density of the semiconductor material from beneath the reorganized surface layer up to a depth of about 1 micron is from about 10⁵/cm to about 10⁸/cm³.

16. The method of claim 12, wherein the defect density of the semiconductor material from beneath the reorganized surface layer up to a depth of about 1 micron is from about 10⁵/cm³ to about 10⁶/cm³.

17. The method of claim 12, wherein the laser radiation has a wavelength between about 200 nm to about 600 nm and a pulse duration of from about 10 femtoseconds to about 400 picoseconds.

18. The method of claim 12, wherein the laser radiation has a wavelength from about 200 nm to about 400 nm.

19. The method of claim 12, wherein the laser radiation has a wavelength from about 500 nm to about 550 nm.

20. The method of claim 12, wherein the laser radiation has a pulse duration of from about 50 femtoseconds to about 100 picoseconds.

21. The method of claim 12, wherein the laser radiation has a pulse duration of from about 500 femtoseconds to about 20 picoseconds.

22. The method of claim 12, wherein the laser radiation has a fluence of from about 1 kj/m² to about 10 kj/m².

23. The method of claim 12, wherein the laser radiation wavelength is such that laser radiation photons have energy that is equal to or greater than a direct band gap of the semiconductor material.

24. The method of claim 12, wherein the semiconductor material is silicon and the laser radiation has a wavelength of less than or equal to about 365 nm.

25. The method of claim 12, wherein the laser radiation is delivered to the target region with a shot number of from about 2 to about 1000.

26. A laser textured semiconductor device having minimal laser-induced material damage, comprising:
a semiconductor material;
a laser-generated textured region formed on a portion of the semiconductor material, the textured region having a reorganized surface layer;
surface features within the textured region, the surface features having an average height of from about 100 nm to about 2 microns, having an average width of from about 100 nm to about 2 micron, and having an average nearest-neighbor distance of from about 100 nm to about 3 microns; and
a defect density within the semiconductor material from beneath the reorganized surface layer up to a depth of about 1 micron is less than or equal to about 10¹²/cm³.

27. The device of claim 26, wherein the surface features have an average height of from about 500 nm to about 1 microns.

28. The device of claim 26, wherein the surface features have an average width of from about 400 nm to about 600 nm.

29. The device of claim 26, wherein the defect density of the semiconductor material from beneath the reorganized surface layer up to a depth of about 1 micron is from about 10⁵/cm to about 10⁸/cm³.

30. The device of claim 26, wherein the defect density of the semiconductor material from beneath the reorganized surface layer up to a depth of about 1 micron is from about 10⁵/cm to about 10⁶/cm³.

31. The device of claim 26, wherein the semiconductor material is silicon.

32. The device of claim 26, wherein the surface features include a member selected from the group consisting of cones, pillars, pyramids, microlenses, sphere-like structures, quantum dots, inverted features, and combinations thereof.
